(19) United States
(12) Patent Application Publication
(10) Pub. No.: US 2018/0204845 A1
(43) Pub. Date: Jul. 19, 2018

(54) Three-Dimensional Vertical Multiple-Time-Programmable Memory Comprising Multiple Re-programmable Sub-Layers

(71) Applicant: Guobiao ZHANG, Corvallis, OR (US)

(72) Inventor: Guobiao ZHANG, Corvallis, OR (US)

(73) Assignee: HangZhou HaiCun Information Technology Co., Ltd., HangZhou (CN)

(21) Appl. No.: 15/919,453

(22) Filed: Mar. 13, 2018

Related U.S. Application Data
(63) Continuation-in-part of application No. 15/488,489, filed on Apr. 16, 2017.

(30) Foreign Application Priority Data
Apr. 16, 2016 (CN) 201610234999.5
Jan. 10, 2018 (CN) 201810024376.4
Jan. 10, 2018 (CN) 201810024500.7
Jan. 17, 2018 (CN) 201810045348.0

(51) Int. Cl. H01L 27/112; H01L 27/06; H01L 27/24; H01L 27/11514; H01L 27/11597; H01L 27/22; H01L 23/525; G11C 17/16

(52) U.S. Cl. CPC H01L 27/11206; H01L 27/0688; H01L 27/249; H01L 27/11514; G11C 17/16; H01L 27/224; H01L 27/2427; H01L 23/5252; H01L 27/11597

(57) ABSTRACT

The present invention discloses a three-dimensional vertical multiple-time-programmable memory (3D-MTP_{V}). It comprises horizontal address lines and memory holes there-through, a re-programmable layer and vertical address lines in said memory holes. The re-programmable layer comprises at least first and second sub-layers with different re-programmable materials. The 3D-MTP_{V} comprises no separate diode layer.

### CROSS-REFERENCE TO RELATED APPLICATIONS

This application is a continuation-in-part of “Three-Dimensional Vertical One-Time-Programmable Memory”, application Ser. No. 15/488,489, filed on Apr. 16, 2017, which claims priority from Chinese Patent Application 201610234999.5, filed on Apr. 16, 2016, in the State Intellectual Property Office of the People's Republic of China (CN), the disclosure of which is incorporated herein by reference in its entirety.

This application also claims priority from Chinese Patent Application 201810024500.7, filed on Jan. 10, 2018; Chinese Patent Application 201810024376.4, filed on Jan. 10, 2018; Chinese Patent Application 201810045348.0, filed on Jan. 17, 2018; in the State Intellectual Property Office of the People's Republic of China (CN), the disclosure of which are incorporated herein by references in their entireties.

### BACKGROUND

### 1. Technical Field of the Invention

The present invention relates to the field of integrated circuit, and more particularly to multiple-time-programmable memory (MTP, also known as re-programmable memory).

### 2. Prior Art

Three-dimensional (3-D) multiple-time-programmable memory (3D-MTP, also known as 3-D re-programmable memory) is a monolithic semiconductor memory. It comprises a plurality of vertically stacked MTP cells. In a conventional MTP, the MTP cells are formed on a two-dimensional (2-D) plane (i.e. on a semiconductor substrate). In contrast, the MTP cells of the 3D-MTP are formed in a three-dimensional (3-D) space. The 3D-OPT has a large storage density and a low storage cost.

U.S. patent application Ser. No. 15/360,895 filed by Hsu on Nov. 23, 2016 discloses a 3-D vertical MTP. It comprises a plurality of horizontal address lines vertically stacked above each other, a plurality of memory holes penetrating the horizontal address lines, a re-programmable layer and a selector layer covering the sidewall of each memory hole, and a plurality of vertical address lines formed in the memory holes. It should be noted that the selector (or, selector layer) is also referred to as diode (or, diode layer), steering element, quasi-conduction layer, or other names in other patents and patent applications. All of them belong to a broad class of diode-like devices whose resistance at the read voltage (i.e. the read resistance) is substantially lower than when the applied voltage has a magnitude smaller than or a polarity opposite to that of the read voltage. Throughout this specification, “diode” is used to represent this class of devices and it is equivalent to selector, steering element, quasi-conduction layer and other names used in other patents and patent applications.

The 3-D vertical memory of Hsu uses a cross-point array. In order to minimize cross-talk between memory cells, the memory cell of Hsu comprises a separate diode layer (i.e. selector in Hsu). A good-quality diode layer is generally thick. For example, a P—N thin-film diode with a good rectifying ratio is at least 100 nm thick. To form a diode layer with such a thickness in the memory hole, the diameter of the memory hole has to be large, i.e. >200 nm. This leads to a lower storage density.

### Objects and Advantages

It is a principle object of the present invention to provide a 3D-MTP with a large storage capacity.

It is a further object of the present invention to simplify the manufacturing process inside the memory holes.

It is a further object of the present invention to minimize the size of the memory holes.

It is a further object of the present invention to provide a properly working 3D-MTP even with leaky MTP cells.

In accordance with these and other objects of the present invention, the present invention discloses a three-dimensional vertical multiple-time-programmable memory (3D-MTP_{V}) comprising multiple re-programmable sub-layers.

### SUMMARY OF THE INVENTION

The present invention first discloses a three-dimensional vertical multiple-time-programmable memory (3D-MTP_{V}) comprising no separate diode layer. It comprises a plurality of vertical MTP strings formed side-by-side on the substrate circuit. Each MTP string is vertical to the substrate and comprises a plurality of vertically stacked MTP cells. To be more specific, the 3D-MTP_{V} comprises a plurality of vertically stacked horizontal address lines (sometimes referred to as word lines). After the memory holes penetrating these horizontal address lines are formed, the sidewall of each memory hole is covered with a re-programmable layer before the memory hole is filled with at least a conductive material. The conductive material in each memory hole forms a vertical address line (sometimes referred to as bit line). The MTP cells are formed at the intersections of the word lines and the bit lines.

To minimize the size of the memory holes, the preferred MTP cell of the present invention comprises no separate diode layer. Without separate diode layer, fewer layers (two instead of three) are formed inside the memory holes and its manufacturing process becomes simpler. In addition, smaller memory holes leads to a larger storage density.

In the preferred MTP cell of the present invention, a diode is formed naturally between the horizontal and vertical address lines. This naturally formed diode, referred to a built-in diode, generally has a poor quality and is leaky. To address this issue, the present invention discloses a full-read mode. For the full-read mode, all MTP cells on a selected word line are read out during a read cycle. The read cycle includes two read phases: a pre-charge phase and a read-out phase. During the pre-charge phase, all address lines (including all word and all bit lines) in an MTP array are charged to a pre-determined voltage. During the read-out phase, after its voltage is raised to the read voltage V_{R}, a selected word line starts to charge all bit lines through the associated MTP cells. By measuring the voltage change on the bit lines, the states of the associated MTP cells can be determined.

Accordingly, the present invention discloses a three-dimensional vertical multiple-time-programmable memory (3D-MTP_{V}), comprising: a semiconductor substrate comprising a substrate circuit; a plurality of vertically stacked horizontal address lines above said semiconductor circuit; a plurality of memory holes through said horizontal address lines; a re-programmable layer on the sidewalls of said memory holes, said re-programmable layer comprising at least first and second sub-layers, wherein said first and second sub-layers comprise different re-programmable materials; a plurality of vertical address lines in said memory holes; a plurality of MTP cells at the intersections of said horizontal address lines and said vertical address lines.

### BRIEF DESCRIPTION OF THE DRAWINGS

FIG. 1A is a z-x cross-sectional view of a first preferred 3D-MTP_{V}; FIG. 1B is its x-y cross-sectional view along the cutline AA′; FIG. 1C is a z-x cross-sectional view of a preferred MTP cell;

FIGS. 2A-2C are cross-sectional views of the first preferred 3D-MTP_{V} at three manufacturing steps;

FIG. 3A is a symbol of the MTP cell; FIG. 3B is a circuit block diagram of a first preferred read-out circuit for an MTP array; FIG. 3C is its signal timing diagram; FIG. 3D shows the current-voltage (I-V) characteristic of a preferred diode layer;

FIG. 4A is a z-x cross-sectional view of a second preferred 3D-MTP_{V}; FIG. 4B is its x-y cross-sectional view along the cutline CC′; FIG. 4C is a circuit block diagram of a second preferred read-out circuit for an MTP array.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. The symbol “/” means a relationship of “and” or “or”.

Throughout the present invention, the phrase “on the substrate” means the active elements of a circuit are formed on the surface of the substrate, although the interconnects between these active elements are formed above the substrate and do not touch the substrate; the phrase “above the substrate” means the active elements are formed above the substrate and do not touch the substrate.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

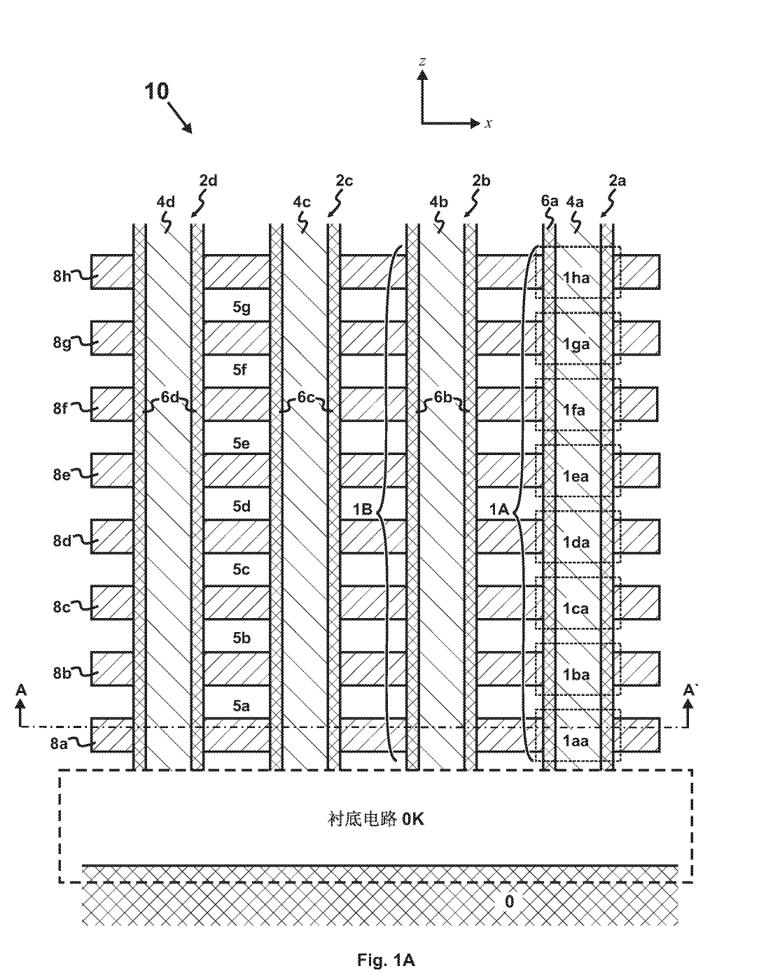

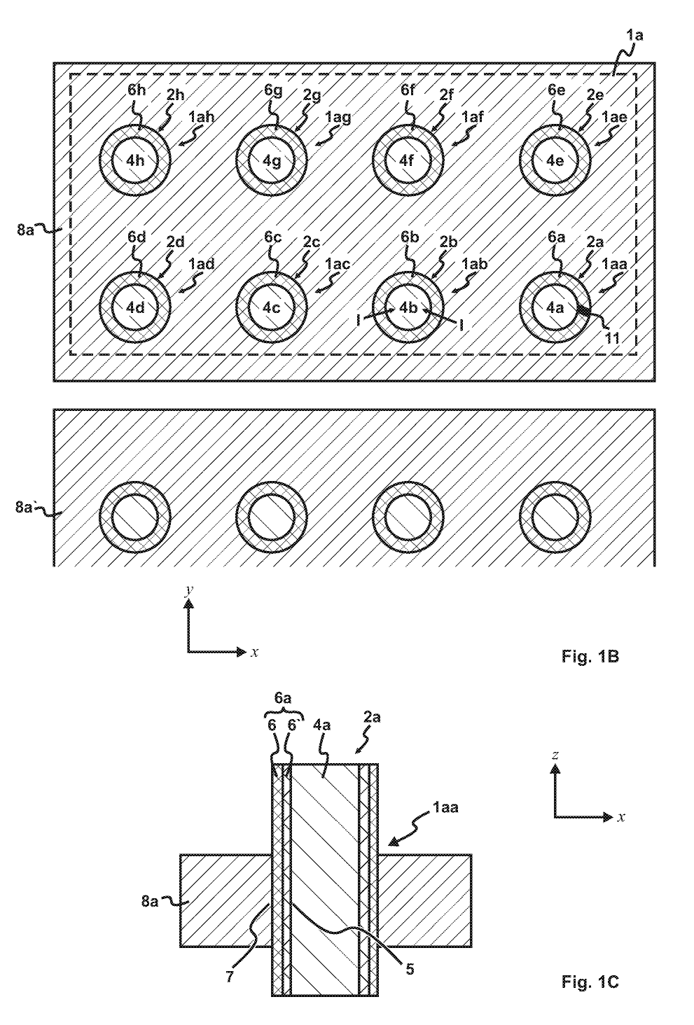

Referring now to FIG. 1A-1C, a first preferred three-dimensional vertical multiple-time-programmable memory (3D-MTP_{V}) comprising no separate diode layer is disclosed. It comprises a plurality of vertical MTP strings 1A, 1B . . . (referred to as MTP strings) formed side-by-side on the substrate circuit 0K. Each MTP string (e.g. 1A) is vertical to the substrate 0 and comprises a plurality of vertically stacked MTP cells 1aa-1ha.

The preferred embodiment shown in this figure is an MTP array 10, which is a collection of all MTP cells sharing at least an address line. It comprises a plurality of vertically stacked horizontal address lines (word lines) 8a-8h. After the memory holes 2a-2d penetrating these horizontal address lines 8a-8h are formed, the sidewalls of the memory holes 2a-2d are covered with a re-programmable layer 6a-6d before the memory holes 2a-2d are filled with at least a conductive material. The conductive material in the memory holes 2a-2d form vertical address lines (bit lines) 4a-4d.

The MTP cells 1aa-1ha on the MTP string 1A are formed at the intersections of the word lines 8a-8h and the bit line 4a. In the MTP cell 1aa, the re-programmable layer 6a comprises at least a phase-change (PCM) material, a resistive RAM (RRAM) material, or other re-programmable materials. PCM and RRAM are well known to those skilled in the art. For example, PCM material has been used as the re-programmable layer in the 3D-XPoint product from Intel and Micron. Examples of the PCM materials include Ge₂Sb₂Te₅ (GST), AgInSbTe, GeTe—Sb₂Te₃ and others. On the other hand, there are many activities on the RRAM materials. Examples of the RRAM materials include NiO, TiO₂, SrTiO₃ and others. The thickness of the re-programmable layer 6a is small, typically in the range of several nanometers to tens of nanometers.

FIG. 1B is its x-y cross-sectional view along the cutline AA′. Each of the horizontal address lines (word lines) 8a, 8a′ is a conductive plate. The horizontal address line 8a is coupled with eight vertical address lines (bit lines) 4a-4h. Eight MTP cells 1aa-1ah are formed at the intersections of the horizontal address 8a and the vertical address lines 4a-4h. All MTP cells 1aa-1ah coupled with a single horizontal address line 8a form an MTP-cell set 1a. Because the horizontal address line 8a is wide, it can be formed by a low-resolution photolithography (e.g. with feature size>60 nm).

To minimize the size of the memory holes, the MTP cell of the present invention does not comprise a separate diode layer. As shown in FIG. 1C, the MTP cell 1aa comprises a separate re-programmable layer 6a, but no separate diode layer. Diode is formed naturally between the horizontal address line 8a and the vertical address line 4a. Because no diode layer is formed therein, the manufacturing process of the memory hole 2a becomes simpler. In addition, smaller memory hole 2a leads to a larger storage density.

The diode formed naturally between the horizontal address line 8a and the vertical address line 4a is a built-in diode. To improve its rectifying ratio, the present invention discloses a 3D-MTP_{V} comprising multiple re-programmable sub-layers. The re-programmable layer 6a of the MTP cell 1aa comprises at least a first sub-layer 6 and a second sub-layer 6′. The first sub-layer 6 and second sub-layer 6′ comprise different re-programmable materials. For example, the first sub-layer 6 comprises NiO, whereas the second sub-layer 6′ comprises TiO₂. Using different sub-layer materials can improve the rectifying ratio of the built-in diode. Furthermore, this rectifying ratio can be further improved by making the interface 7 of the horizontal address line 8a and the re-programmable layer 6a substantially different from the interface 5 of the vertical address line 4a and the re-programmable layer 6a.

Besides using different sub-layer materials, the rectifying ratio of the built-in diode can be further improved by using different address-line materials. In a first preferred embodiment, the horizontal address line 8a comprises a P-type semiconductor material, while the vertical address line 4a comprises an N-type semiconductor material. They form a semiconductor diode. In a second preferred embodiment, the horizontal address line 8a comprises a metallic material, while the vertical address line 4a comprises a semiconductor material. They form a Schottky diode. In a third preferred embodiment, the horizontal address line 8a comprises a semiconductor material, while the vertical address line 4a comprises a metallic material. They form a Schottky diode. In a fourth preferred embodiment, the horizontal address line 8a comprises a first metallic material, while the vertical address line 4a comprises a second metallic material. The first and second metallic material are different metallic materials.

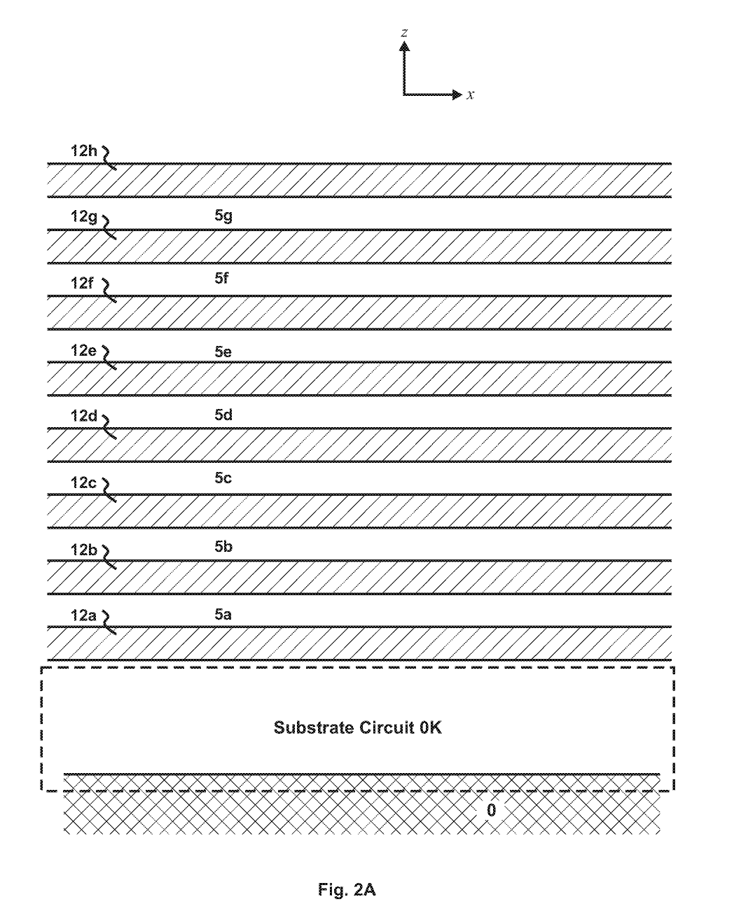

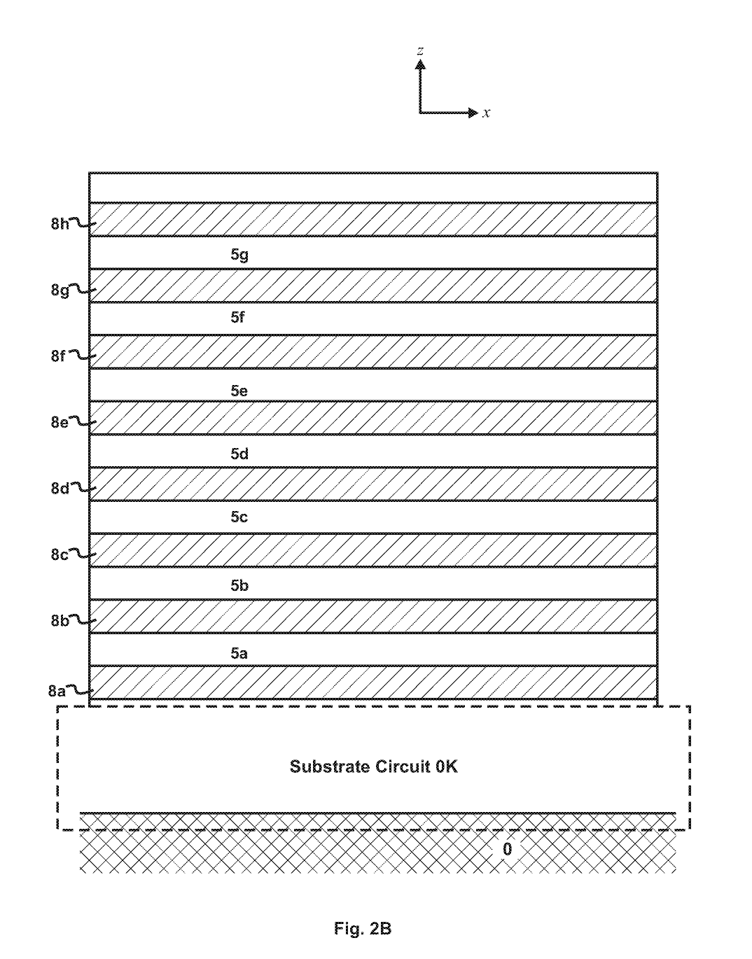

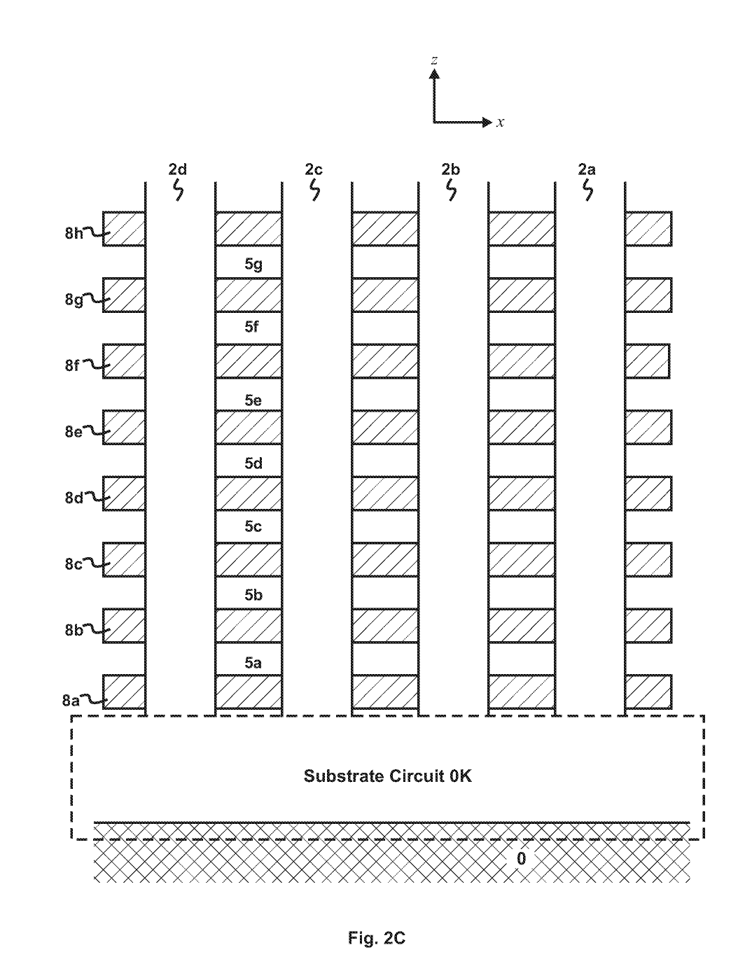

Referring now to FIGS. 2A-2C, three manufacturing steps for the preferred 3D-MTP_{V} are shown. First of all, vertically stacked horizontal address-line layers 12a-12h are formed in continuously forming steps (FIG. 2A). To be more specific, after the substrate circuit 0K (including transistors and the associated interconnects) are planarized, a first horizontal address-line layer 12a is formed. The first horizontal address-line layer 12a is just a plain layer of conductive materials and contains no patterns. Then a first insulating layer 5a is formed on the first horizontal address-line layer 12a. Similarly, the first insulating layer 5a contains no patterns. Repeating the above process until alternate layers of the horizontal address-line layers and the insulating layers (a total of M layers) are formed. “Continuously forming steps” means that these forming steps (for the horizontal address-line layer and the insulating layer) are carried out continuously without any in-between pattern-transfer steps (including photolithography). Without any in-between pattern-transfer steps, excellent planarization can be achieve. As a result, the 3D-MTP_{V} comprising tens to hundreds of horizontal address-line layers can be formed.

A first etching step is performed through all horizontal address-line layers 12a-12h to form a stack of horizontal address lines 8a-8h in (FIG. 2B). This is followed by a second etching step to form memory holes 2a-2d through all horizontal address lines 8a-8h (FIG. 2C). The sidewall of the memory holes 2a-2d is covered by a re-programmable layers 6a-6d before the memory holes 2a-2d are filled with at least a conductive material to form the vertical address lines 4a-4d (FIG. 1A).

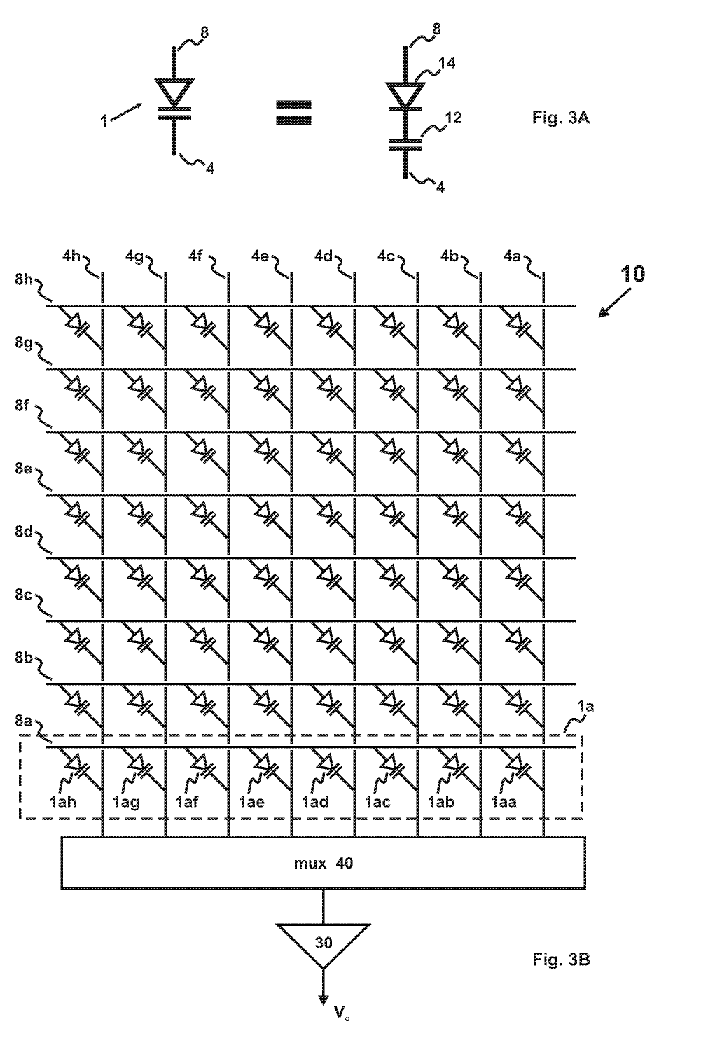

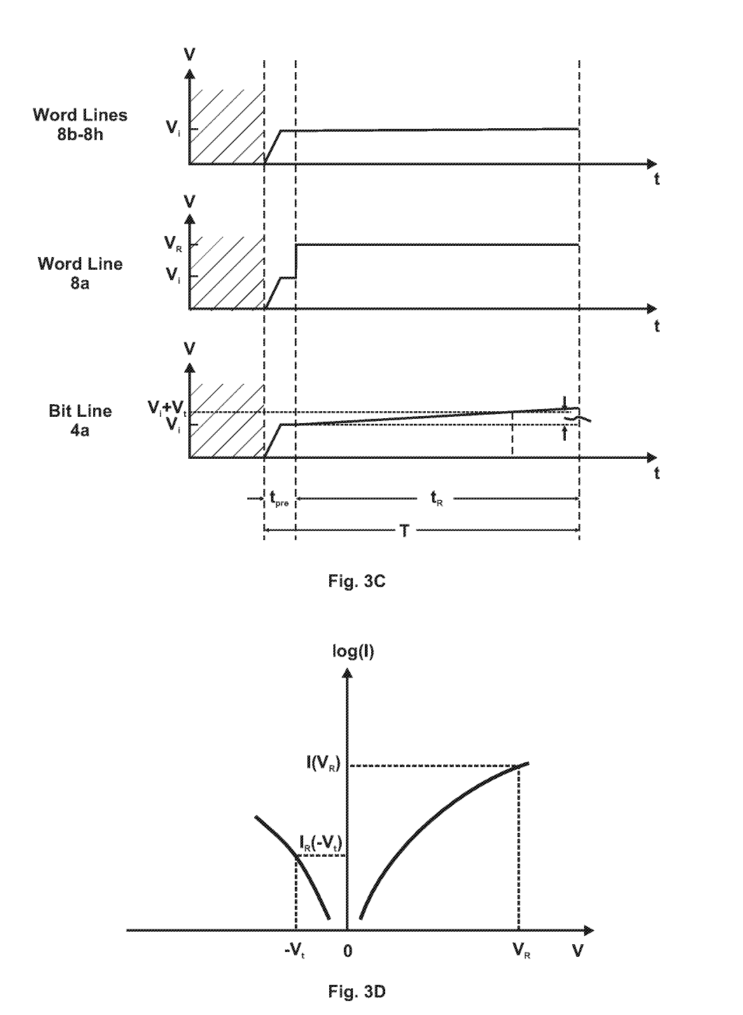

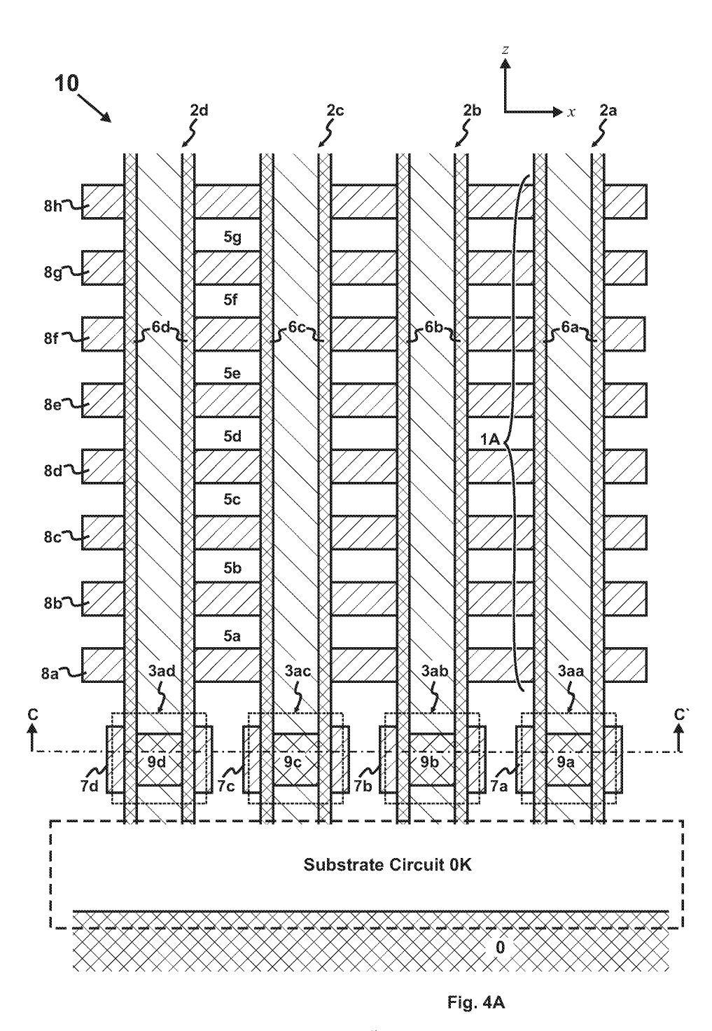

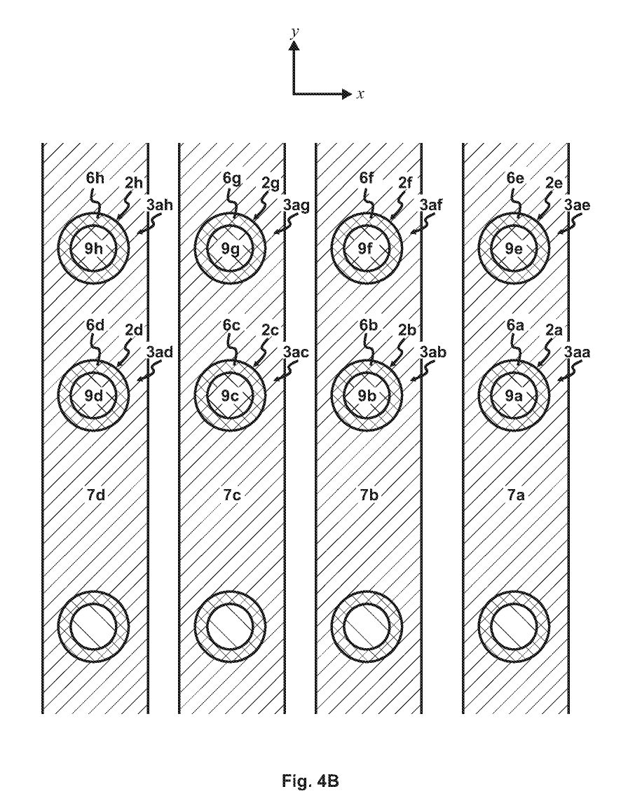

FIG. 3A is a symbol of the MTP cell 1. The MTP cell 1, located between a word line 8 and a bit line 4, comprises a re-programmable layer 12 and a diode 14. The resistance of the re-programmable layer 12 can be switched from high to low or vice versa. The resistance of the diode 14 at the read voltage is substantially lower than when the applied voltage has a magnitude smaller than or polarity opposite to that of the read voltage.

Although a diode 14 is drawn in the symbol of the MTP cell 1, there is no physical diode in the present invention. The diode 14 is formed naturally between the word line 8 and the bit lines 4. This naturally formed diode 14, referred to a built-in diode, generally has a poor quality and is leaky. To address this issue, the present invention discloses a full-read mode. For the full-read mode, all MTP cells on a selected word line are read out during a read cycle.

FIG. 3B discloses a first preferred read-out circuit for an MTP array 10. It runs in the full-read mode. In this preferred embodiment, the horizontal address lines 8a-8h are word lines, while the vertical address lines 4a-4h are bit lines. An MTP array 10 comprises the word lines 8a-8h, the bit lines 4a-4h, and the MTP cells 1aa-1ad . . . located at their intersections. Its peripheral circuits (located on the substrate 0 and is not part of the MTP array 10) comprise a multiplexor 40 and an amplifier 30. In this preferred embodiment, the multiplexor 40 is a 4-to-1 multiplexor.

FIG. 3C is its signal timing diagram. A read cycle T includes two read phases: a pre-charge phase tₚᵣₑ and a read-out phase t_{R}. During the pre-charge phase tₚᵣₑ, all address lines 8a-8h, 4a-4h in the MTP array 10 are charged to a pre-determined voltage (e.g. an input bias voltage Vᵢ, of the amplifier 30). During the read-out phase t_{R}, all bit lines 4a-4h are floating. The voltage on a selected word line (e.g. 8a) is raised to the read voltage V_{R}, while voltage on other word lines 8b-8h remains at the input bias voltage Vᵢ. After this, the selected word line 8a starts to charge all bit lines 4a-4h through the MTP cells 1aa . . . and the voltages on the bit lines 4a-4h begin to rise. The multiplexor 40 sends the voltage on each bit line (e.g. 4a) to the amplifier 30. When this voltage exceeds the threshold voltage V_{T} of the amplifier 30, the output V_{O} is toggled. At the end of the read cycle T, the states of all MTP cells 1aa-1ah in the MTP-cell set 1a are determined.

FIG. 3D shows the current-voltage (I-V) characteristic of a preferred diode layer. Because the V_{T} of the amplifier 30 is relatively small (˜0.1V or smaller), the voltage changes delta (V) on the bit lines 4a-4h during the above measurement are small, i.e. delta (V)˜V_{T}. The reverse voltage on the unselected MTP cells (e.g. 1ca) is ˜V_{T}. As long as the I-V characteristic of the diode satisfies I(V_{R})>>n*I(−V_{T}), the 3D-MTP_{V} would work properly. Here, n is the number of MTP cells on a bit line (e.g. 4a). It should be noted that, because the value of V_{R} (several volts) is far larger than that of the −V_{T} (˜0.1V), the above condition can be easily met even for leaky MTP cells.

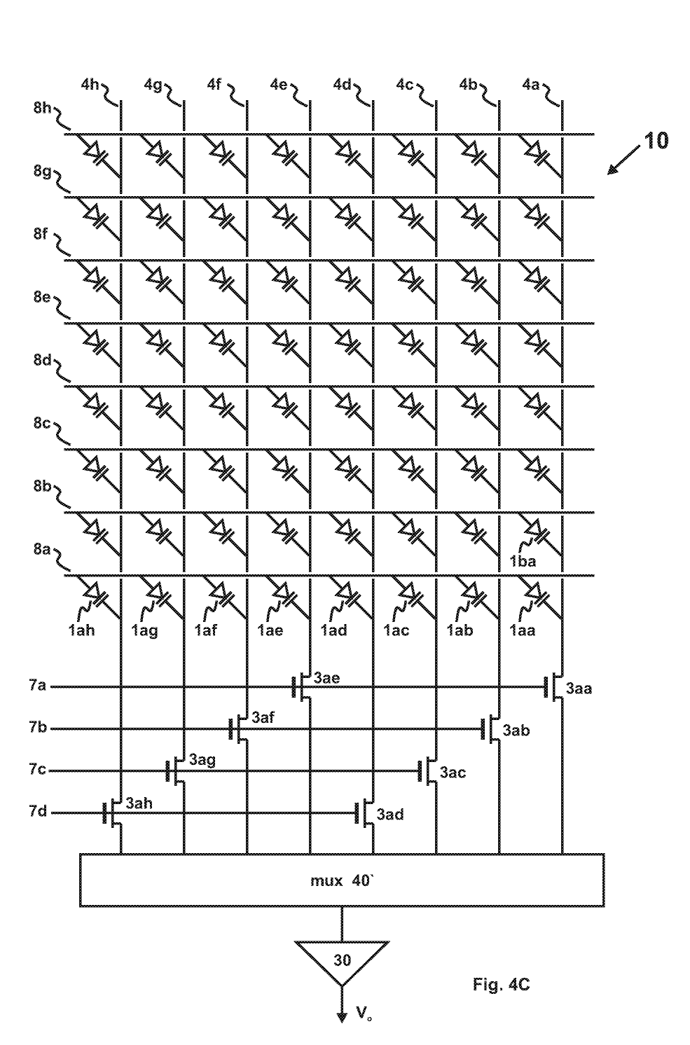

To facilitate address decoding, vertical transistors are formed on the sidewalls of the memory holes. FIGS. 4A-4C disclose a second preferred 3D-MTP_{V} 10 comprising vertical transistors 3aa-3ad. The vertical transistor 3aa is a pass transistor comprising a gate 7a, a gate dielectric 6a and a channel 9a (FIG. 4A). The channel 9a is formed in the semiconductor material filled in the memory hole 2a. Its doping could be same as, lighter than, or opposite to that of the vertical address line 4a. The gate 7a surrounds the memory holes 2a, 2e and controls the pass transistors 3aa, 3ae (FIG. 4B); the gate 7b surrounds the memory holes 2b, 2f and controls the pass transistors 3ab, 3af; the gate 7c surrounds the memory holes 2c, 2g and controls the pass transistors 3ac, 3ag; the gate 7d surrounds the memory holes 2e, 2h and controls the pass transistors 3ae, 3ah. The pass transistors 3aa-3ah form at least a decoding stage (FIG. 4C). In one preferred embodiment, when the voltage on the gate 7a is high while the voltages on the gates 7b-7d are low, only the pass transistors 3aa, 3ae are turned on, with other pass transistors off. The substrate multiplexor 40′ is a 2-to-1 multiplexor which selects a signal from the bit lines 4a, 4e. By forming vertical transistors 3aa-3d in the memory holes 2a-2d, the decoder design could be simplified.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A three-dimensional vertical multiple-time-programmable memory (3D-MTP_{V}), comprising:
a semiconductor substrate comprising a substrate circuit;
a plurality of vertically stacked horizontal address lines above said semiconductor circuit;
a plurality of memory holes through said horizontal address lines;
a re-programmable layer on the sidewalls of said memory holes, said re-programmable layer comprising at least first and second sub-layers, wherein said first and second sub-layers comprise different re-programmable materials;
a plurality of vertical address lines in said memory holes;
a plurality of MTP cells at the intersections of said horizontal address lines and said vertical address lines.

2. The 3D-MTP_{V} according to claim 1, wherein said re-programmable layer comprises at least a phase-change (PCM) material.

3. The 3D-MTP_{V} according to claim 1, wherein said re-programmable layer comprises at least a resistive RAM (RRAM) material.

4. The 3D-MTP_{V} according to claim 1, further comprising:
a first interface between said first sub-layer and selected one of said horizontal address lines;
a second interface between said second sub-layer and selected one of said vertical address lines;
wherein said first and second interfaces are different.

5. The 3D-MTP_{V} according to claim 1, wherein said horizontal address lines and said vertical address lines comprise different conductive materials.

6. The 3D-MTP_{V} according to claim 1, wherein said horizontal address line, said re-programmable layer and said vertical address line form a built-in diode.

7. The 3D-MTP_{V} according to claim 6, wherein the resistance of said diode is substantially lower than when the applied voltage has a magnitude smaller than or a polarity opposite to that of the read voltage.

8. The 3D-MTP_{V} according to claim 7, wherein all MTP cells coupled to a selected horizontal address line are read out in a single read cycle.

9. The 3D-MTP_{V} according to claim 8, wherein the I-V characteristics of said built-in diode satisfies I(V_{R})>>n*I(−V_{T}), where V_{R} is the read voltage on said selected horizontal address line; V_{T} is the toggle voltage of a selected vertical address line; n is the number of MTP cells on said selected horizontal address line.

10. The 3D-MTP_{V} according to claim 1, wherein said MTP cells form an MTP string.

11. The 3D-MTP_{V} according to claim 10, further comprising a vertical transistor coupled to said MTP string.

12. The 3D-MTP_{V} according to claim 11, wherein said vertical transistor is formed in a first portion of said memory hole, and said MTP string is formed in a second portion of said memory hole.
